(19) United States
(12) Patent Application Publication
(10) Pub. No.: US 2026/0212715 A1
(43) Pub. Date: Jul. 23, 2026

(54) STEER-BY-WIRE ELECTROMAGNETIC-COMPATIBILITY TESTING SYSTEM AND METHOD FOR INTELLIGENT CONNECTED VEHICLE

(71) Applicant: CHINA AUTOMOTIVE TECHNOLOGY AND RESEARCH CENTER CO., LTD., Tianjin (CN)

(72) Inventors: Guotian JI, Tianjin (CN); Hui RONG, Tianjin (CN); Hanbing WU, Tianjin (CN); Shuo ZHAO, Tianjin (CN); Guangyu ZHANG, Tianjin (CN); Yifu DING, Tianjin (CN); Xiaoyi HOU, Tianjin (CN); Xu ZHANG, Tianjin (CN); Yunlei ZHANG, Tianjin (CN); Jiarui ZHANG, Tianjin (CN); Haiming LIU, Tianjin (CN); Siyang ZHAO, Tianjin (CN); Xiaoting ZHANG, Tianjin (CN); Shuang LV, Tianjin (CN); Junfan CHEN, Tianjin (CN); Mohan WEI, Tianjin (CN); Jie HAN, Tianjin (CN); Zhiduo XIAO, Tianjin (CN); Qinghao WEN, Tianjin (CN); Yan FAN, Tianjin (CN)

(73) Assignee: CHINA AUTOMOTIVE TECHNOLOGY AND RESEARCH CENTER CO., LTD., Tianjin (CN)

(21) Appl. No.: 19/444,517

(22) Filed: Jan. 9, 2026

(30) Foreign Application Priority Data
Jan. 17, 2025 (CN) 202510073700.1

(51) Int. Cl. G07C 5/10; G06T 7/73; G07C 5/08

(52) U.S. Cl. CPC G07C 5/10; G06T 7/73; G07C 5/0808; G06T 2207/30208; G06T 2207/30252

(57) ABSTRACT

According to a steer-by-wire electromagnetic-compatibility testing system, through controlling the steering executor on the steering wheel, a vehicle steering system is operated to rotate at a set angular speed to a set angle, the camera is utilized for acquiring the images of the checkerboard deployed at the outer side of the steered wheel, and the images are analyzed on the basis of the processor to obtain information such as the actual steering angle, so that the steering function testing result is obtained.

### CROSS-REFERENCE TO RELATED APPLICATIONS

This application claims priority to Chinese Patent Application No. 202510073700.1, filed on Jan. 17, 2025, the content of which is incorporated herein by reference in its entirety.

### TECHNICAL FIELD

The present application belongs to the field of vehicles, and specifically relates to a steer-by-wire electromagnetic-compatibility testing system and method for an intelligent connected vehicle.

### BACKGROUND

A steering system for a vehicle is responsible for lateral control for the vehicle, and in a traditional steering system, a driver transmits operation of a steering wheel to steered wheels through mechanical apparatuses (such as a steering gear and a tie rod), thus realizing steering of the vehicle. Early mechanical hydraulic power-assisted steering systems, as well as electro-hydraulic power-assisted steering systems, electric power-assisted steering systems, etc. which are widely applied in modern times all belong to steering systems based on mechanical rigid connections. These mechanical systems are optimized in design for steering force transmission, reduce operation and control burdens of drivers through power assistance, and improve stability and smoothness of vehicles. However, due to limitations of mechanical structures, steering angle transmission characteristics cannot be flexibly adjusted, and refined control requirements needed for autonomous driving are difficultly met.

Intelligentization has become a future development direction of the vehicle industry, autonomous driving is a core technology of vehicle intelligence, and research and application for a steer-by-wire technology is a key link in realization for the autonomous driving. With maturity of an electronic technology and an automatic control technology, and popularization of a communication technology, a steer-by-wire system has emerged and is gradually replacing traditional mechanical connections. The steer-by-wire system cancels mechanical rigid connection components between a steering wheel and steered wheels, and realizes steering through electronic signal control. The steer-by-wire system not only has advantages of a traditional mechanical steering system, but also optimizes angle transmission characteristics, and provides control flexibility which cannot be realized by the traditional mechanical system. In the steer-by-wire system, an operation signal of a driver is converted into an electric signal through a sensor, and after analysis and processing, the electric signal is transmitted to a steering execution mechanism through a conductive wire, so that steering control is realized. Therefore, the steer-by-wire system may theoretically realize any steering angle, and surpass the limitations of the mechanical structures.

In an application process, a key consideration needs to be given for several characteristics with regard to performance of the steer-by-wire system: firstly, rotation synchronization between the steering wheel and the wheels, i.e., a steering delay; secondly, whether the steering wheel can precisely control the wheels to rotate to specified angles or not; and finally, whether automatic adjustment for a steering gear ratio at different vehicle speeds meets design requirements or not. With increasing of complexity of the steer-by-wire system, normal running of each environment relies on normal working of various electronic systems. Especially under an external condition of electromagnetic interference, system faults may cause abnormalities in an autonomous driving function, and even lead to loss of vehicle control, thus resulting in casualties and severe property damage. Therefore, testing for the steer-by-wire system in terms of electromagnetic compatibility and fault tolerance needs to be sufficiently precise to guarantee safety and reliability of the steer-by-wire system in autonomous driving applications.

### SUMMARY

The present application discloses a steer-by-wire electromagnetic-compatibility testing system and method for an intelligent connected vehicle, for solving a problem of incapability of accurately testing a steer-by-wire function of a vehicle under a condition of electromagnetic interference in the prior art.

In order to solve the above technical problem, an example of the present application discloses following technical solutions.

One aspect of the present application provides a steer-by-wire electromagnetic-compatibility testing system for an intelligent connected vehicle, and the testing system is applied to test a steer-by-wire function of the vehicle in an electromagnetic environment, and includes:
a steering executor fixed to a steering wheel, and configured to carry out steering operation according to a received steering instruction;
a circular checkerboard fixed to an outer side of a steered wheel, wherein the midpoint of the checkerboard is coincided with the midpoint of the steered wheel;
a camera fixedly connected with the vehicle, and configured to shoot images of the complete checkerboard in an axle direction of the steered wheel; and
a processor which is in communication connection with the steering executor and the camera, and configured to send the steering instruction to the steering executor, acquire the checkerboard images shot by the camera, and obtain a steering function testing result according to a steering situation of the steering executor and contour changes of the checkerboard in the images.

The steer-by-wire electromagnetic-compatibility testing system and method for the intelligent connected vehicle, which are disclosed by the example of the present application can solve a technical conflict of incapability of implementing steer-by-wire black-box precise testing for an intelligent connected vehicle, and a testing system and method with high adaptability and capable of being deployed in an electromagnetic-compatibility darkroom are provided. Through controlling the steering executor on the steering wheel, a vehicle steering system is operated to rotate at a set angular speed to a set angle, the camera is utilized for acquiring the images of the checkerboard deployed at the outer side of the steered wheel, and the images are analyzed on the basis of the processor to obtain information such as the actual steering angle, so that the steering function testing result is obtained. Whole-vehicle-level steer-by-wire testing is realized, and a new testing guarantee solution is provided for safe running of the steer-by-wire system of the intelligent connected vehicle. The testing system and method which are disclosed by the present application have advantages such as high adaptability, low cost, and convenient deployment, are applicable to autonomous vehicles with various sensor architectures and function/scene definitions, have an extremely-high industrialized application value, and can meet current and future needs for steer-by-wire testing evaluation.

The summary parts are provided to introduce selection for concepts in a simplified form, which will be further described in specific implementation manners below. The summary parts are not intended to identify important features or necessary features of the present application, and also not intended to limit the scope of the present application.

### BRIEF DESCRIPTION OF THE DRAWINGS

The above and other objectives, features, and advantages of the present application will become more apparent through a more detailed description for exemplary examples of the present application in conjunction with the drawings, where the same reference labels usually represent the same components in the exemplary examples of the present application.

FIG. 1a is a schematic structure diagram I of a steer-by-wire electromagnetic-compatibility testing system for an intelligent connected vehicle, which is provided by an example of the present application.

FIG. 1b is a schematic structure diagram II of a steer-by-wire electromagnetic-compatibility testing system for an intelligent connected vehicle, which is provided by an example of the present application.

FIG. 2 is a schematic structure diagram of a processor sub-unit which is provided by the example of the present application.

FIG. 3 is a schematic diagram of contour changes of a checkerboard in images, which are provided by the example of the present application.

FIG. 4 is a schematic diagram of an actual rotation angle of a steered wheel, which is provided by the example of the present application.

FIG. 5 is a steering comparison diagram between a steering executor and the steered wheel, which is provided by the example of the present application.

FIG. 6 is a schematic flow diagram of a steer-by-wire electromagnetic-compatibility testing method for an intelligent connected vehicle, which is provided by the example of the present application.

### DETAILED DESCRIPTION OF THE EMBODIMENTS

The examples of the present application will be described in more detail below with reference to the drawings. Although the examples of the present application are shown in the drawings, it should be understood that, the present application may be realized in various forms and should not be limited by the examples illustrated herein. On the contrary, these examples are provided to enable the present application to be more thorough and complete, and to enable the scope of the present application to be completely communicated to those skilled in the art.

The term “including” and variations thereof used herein indicate open-ended inclusions, i.e., “including but not limited to”. Unless otherwise stated, the term “or” indicates “and/or”. The term “based on” means “at least partially based on”. The terms “one exemplary example” and “one example” indicate “at least one exemplary example”. The term “another example” indicates “at least one additional example”. The terms “first”, “second”, etc. may refer to different or the same objects. Other explicit and implicit definitions may further be included below.

A steer-by-wire system of a vehicle cancels direct connections between traditional mechanical and hydraulic components, and no longer realizes steering through physical components between a steering wheel and wheels, but instead completely relies on an electrical signal to transmit a steering instruction. In the example disclosed by the present application, electromagnetic interference that the vehicle may encounter during actual running is simulated by means of an electromagnetic-compatibility (EMC) testing device, so that performance of the steer-by-wire system in an electromagnetic environment is detected.

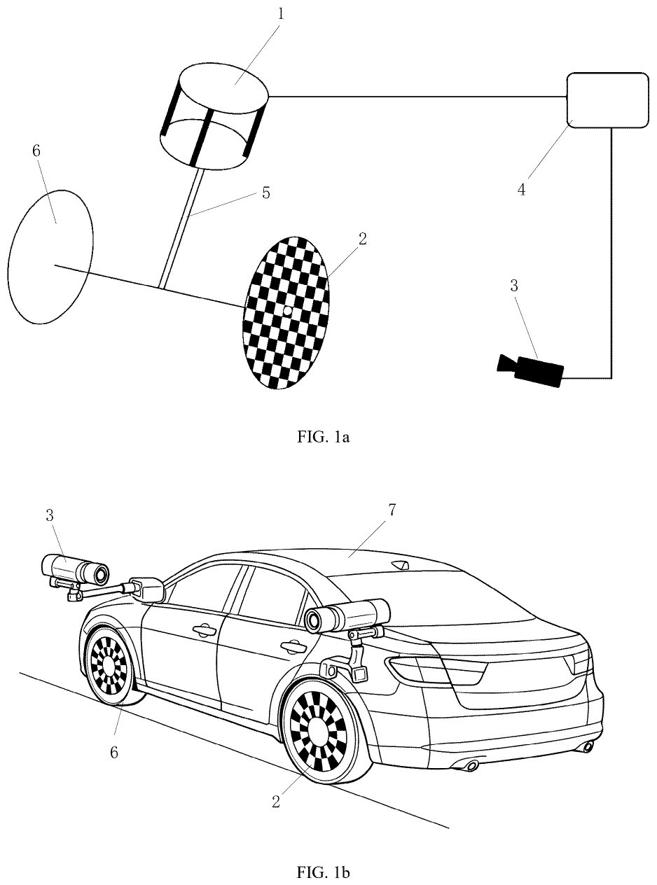

FIG. 1a and FIG. 1b are schematic structure diagrams of a steer-by-wire electromagnetic-compatibility testing system for an intelligent connected vehicle, which is provided by the example of the present application, and the testing system is applied to test a steer-by-wire function of the vehicle in an electromagnetic environment. As shown in FIG. 1, the testing system includes a steering executor 1, a checkerboard 2, a camera 3, and a processor 4.

In the example disclosed by the present application, the steering executor 1 is installed on a steering wheel 5 and responsible for carrying out corresponding steering operation according to a received steering instruction. For example, a testing person transmits a steering signal to the processor 4, after receiving the steering signal, the processor 4 carries out signal processing and calculation in conjunction with other data (such as a vehicle speed, and a road situation), thus generating an optimized steering instruction, and the steering instruction is sent to the steering executor 1 to instruct the steering executor 1 to carry out corresponding rotation, thus driving the steering wheel 5 to rotate.

In the example disclosed by the present application, the checkerboard 2 is a circular mark with a uniformly-distributed pattern of black and white grids, where the pattern of black and white grids may be black and white square grids, the checkerboard 2 is fixed to an outer side of a steered wheel 6, the midpoint of the checkerboard 2 is coincided with the midpoint of the steered wheel 6, and a radius of the checkerboard 2 is less than that of the steered wheel 6.

The pattern on the checkerboard 2 can provide a plurality of symmetrical feature points, so that high-precision image recognition and measurement are facilitated. The checkerboard 2 is arranged at the outer side of the steered wheel 6, with the radius less than that of the steered wheel 6, so that the checkerboard 2 may be guaranteed to rotate synchronously with the steered wheel 6.

The center point of the checkerboard 2 is precisely coincided with the center point of the steered wheel 6, that is, the center points of the checkerboard 2 and the steered wheel 6 are overlapped in a plane parallel to the outer side of the steered wheel 6, and a circular structure of the checkerboard 2 guarantees consistent measurement for rotation angles in all directions, so that errors caused by irregular shapes are avoided.

In the example disclosed by the present application, the camera 3 is connected with a vehicle body of the vehicle 7 through a support, the support is an adjustable support, and capable of adjusting the center point of an optical axis of the camera 3 to be located on an extension line of an axle direction before testing, so that the camera 3 can shoot images of the complete checkerboard 2 in the axle direction of the steered wheel 6.

In a specific implementation disclosed by the present application, the camera 3 is a high-speed camera which can capture subtle changes of the checkerboard 2 in the images at an extremely-high frame rate during rotation of the vehicle wheel, so that precise measurement data acquisition is guaranteed.

The center point of the optical axis of the camera 3 is located on an extension line of the axle direction, and alignment of the centers of the images of the checkerboard 2 and the center of the steered wheel 6 are ensured, so that not only can changes of a rotation angle of the steered wheel 6 be accurately captured, but also analysis for a deformation amount of the checkerboard 2 through an image processing algorithm is facilitated.

Under the capture of the high-resolution camera 3, an edge of the checkerboard 2 can reflect the rotation angle of the steered wheel 6. During rotation of the steered wheel 6, the images shot by the camera 3, of the checkerboard 2, generate corresponding deformations, such as becoming elliptical. An actual rotation angle of the steered wheel 6 may be calculated through a deformation degree.

In the example disclosed by the present application, one circular checkerboard 2 is arranged at an outer side of each steered wheel 6, and moreover, each steered wheel 6 is correspondingly provided with a camera 3 capable of shooting the complete checkerboard 2 on the steered wheel 6, so that testing for each steered wheel 6 is realized. A testing content for each steered wheel 6 is completely the same, therefore, in the example disclosed by the present application, only a steering testing process for one of the steered wheels 6 is described, and the testing contents for the remaining steered wheels 6 will not be further elaborated.

The processor 4 is in communication connection with the steering executor 1 and the camera 3, and can send the steering instruction to the steering executor 1, acquire the checkerboard images shot by the camera 3, and obtain a steering function testing result according to a steering situation of the steering executor 1 and contour changes of the checkerboard 2 in the images.

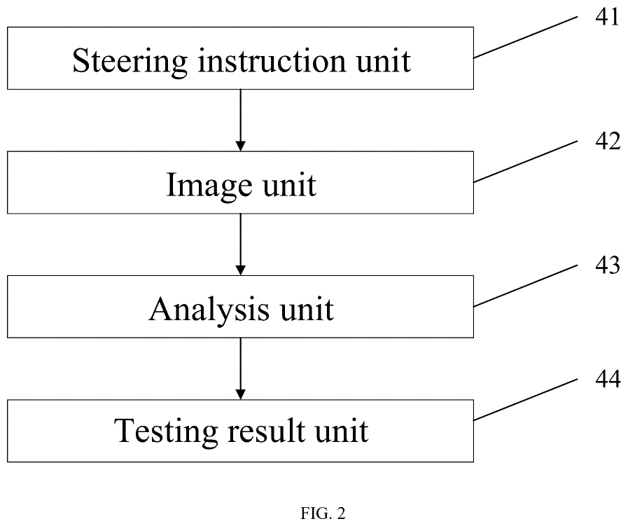

In one example disclosed by the present application, as shown in FIG. 2, the processor 4 includes a steering instruction unit 41, an image unit 42, an analysis unit 43, and a testing result unit 44.

The steering instruction unit 41 is in communication connection with the steering executor 1, and can generate a steering instruction according to steering data input by the testing person, and send the steering instruction to the steering executor 1, where the steering data includes a steering speed, a steering angle, step time, and dwell time. For example, the steering speed is ω, the steering angle is θ, the step time is ΔT1, the dwell time is ΔT2, and an intention of the steering instruction is to: enable the vehicle 7 to rotate by the angle θ at the steering speed ω and then run for the time ΔT1, and then stop running for the time ΔT2.

The image unit 42 is in communication connection with the camera 3, and used for, after receiving a shooting instruction, controlling the camera 3 to continuously shoot the images of the checkerboard 2, storing the images transmitted by the camera 3, and recording shooting time of each image.

The image unit 42 immediately activates the camera 3 after receiving the shooting instruction, and enables the camera 3 to be in a continuous shooting mode. In this mode, the checkerboard images can be captured at a specified frame rate within a short period of time, so that it is ensured that the captured images can reflect a real-time state of the checkerboard 2. For example, the camera 3 rapidly shoots the images of the checkerboard 2 for many times at a small time interval.

The image unit 42 will carry out real-time monitoring on each frame of image shot by the camera 3, and simultaneously record shooting time of each image, so as to form an “image-timestamp” pair. Therefore, precise tracking for the changes of the checkerboard 2 in a steering process is realized, and especially during high-frequency shooting, every minor deformation of the checkerboard 2 in the images may be finely captured.

The image unit 42 stores the continuously-shot image data along with corresponding timestamps, and transmits the image data and the timestamps to the analysis unit.

The analysis unit 43 is in communication connection with the image unit 42, and used for obtaining the first starting time and the first stopping time when the steered wheel 6 completes each steering action.

The ith steering of the steered wheel 6 is taken as an example, the first starting time

$${t}_{i}^{b e g i n}$$

and the first stopping time

$${t}_{i}^{e n d}$$

may be obtained in a following manner:

a contour of the checkerboard 2 in the images is continuously monitored, for example, the contour of the checkerboard 2 may be detected through measuring a distance parallel to a running ground and between the midpoint and an edge of the checkerboard 2 in the images.

Whether the contour of the checkerboard 2 in the images changes or not after stable time exceeds first preset time is judged, that is, whether the steered wheel 6 starts to steer or not is judged, if so, time of changing is taken as the starting time

$${t}_{i}^{begin} ,$$

and whether the contour of the checkerboard 2 in the images stops changing or not, and whether stable time after changing is stopped exceeds second preset time or not are continued to be judged, that is, whether the steered wheel 6 completes steering action or not is judged, if so, the time of stopping changing is taken as the stopping time

$${t}_{i}^{e n d} ,$$

where both the first preset time and the second preset time are short time periods, aimed at determining whether the steered wheel 6 is currently in a steering process or not. For example, both the first preset time and the second preset time may be 100 milliseconds, and if the steered wheel 6 does not steer within time exceeding 100 milliseconds but starts to steer at certain time, the time is taken as the starting time; and if the steered wheel 6 does not steer again within 100 milliseconds after stopping steering, the time of stopping steering is taken as the stopping time.

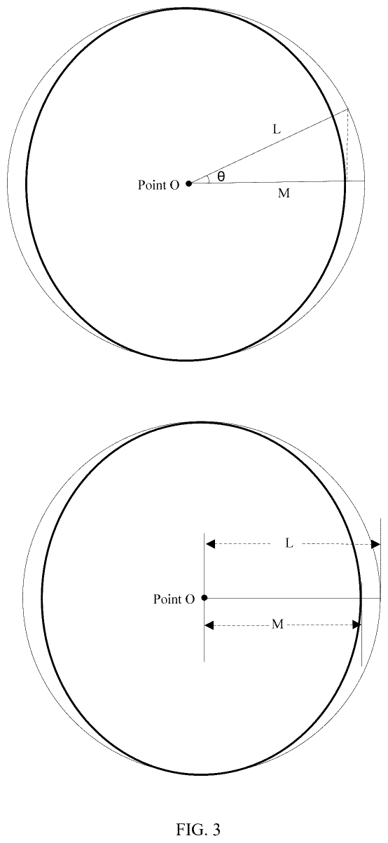

As shown in FIG. 3, after the starting time

$${t}_{i}^{begin}$$

and the stopping time

$${t}_{i}^{e n d}$$

of the ith steering of the steered wheel 6 are determined, a distance L parallel to the running ground and between the midpoint O and the edge of the checkerboard 2 is measured in the image corresponding to the

$${t}_{i}^{begin} ,$$

a distance M parallel to the running ground and between the midpoint O and the edge of the checkerboard 2 is measured in the image corresponding to the

$${t}_{i}^{e n d} ,$$

and as shown in FIG. 4, an actual rotation angle θᵢ of the steered wheel 6 during the ith steering is calculated according to a following formula:

$${θ}_{i} = {cos}^{- 1} \frac{M}{L}$$

where 1≤i≤n, and n is a total number of steering times of the steered wheel 6 during testing.

The testing result unit 44 is respectively in communication connection with the analysis unit 43 and the steering executor 1, and used for acquiring starting time and stopping time of each rotation of the steering executor 1.

The ith steering of the steering executor 1 is taken as an example, a sensor on the steering executor 1 is adopted to obtain the second starting time

$${T}_{i}^{begin} ,$$

the second stopping time

$${T}_{i}^{end} ,$$

and an actual steering angle Φᵢ of steering of the steering executor 1, and obtain a steering function testing result according to the starting time

$${t}_{i}^{begin} ,$$

the stopping time

$${t}_{i}^{e n d} ,$$

and the actual rotation angle θᵢ of the ith steering of the steered wheel 6, where the steering function testing result at least includes a steering angle error and a steering delay.

In the example disclosed by the present application, the testing result unit 44 includes a steering angle error unit and a steering delay unit.

The steering angle error unit is used for calculating a steering angle error; of the steered wheel 6 relative to the steering executor 1 after the ith steering according to the actual rotation angle of the steered wheel 6 after the ith steering and the actual steering angle of the steering executor 1 after executing steering action for the ith time.

$$Steering angle {error}_{i} = {θ}_{i} - {Φ}_{i}$$

A value of the steering angle error can reflect synchronization of a steering function, and in the case of a small error, it indicates that there is high consistency between the steering executor 1 and the steered wheel 6; whereas, in the case of a large error, it indicates that there may be situations such as a delay, friction, or electromagnetic interference in response of the steered wheel 6.

The steering delay unit is used for calculating a steering delay of the steered wheel 6 relative to the steering executor 1 after the ith steering according to the starting time and the stopping time of the ith steering of the steered wheel 6, as well as the starting time and the stopping time when the steering executor 1 executes steering action for the ith time.

In the example disclosed by the present application, a testing content for the steering system may be: the vehicle 7 is steered and then moves forwards for time ΔT, then stops running for the same time ΔT, the process is repeated for many times, such as 10 times, and a testing result of each time is analyzed.

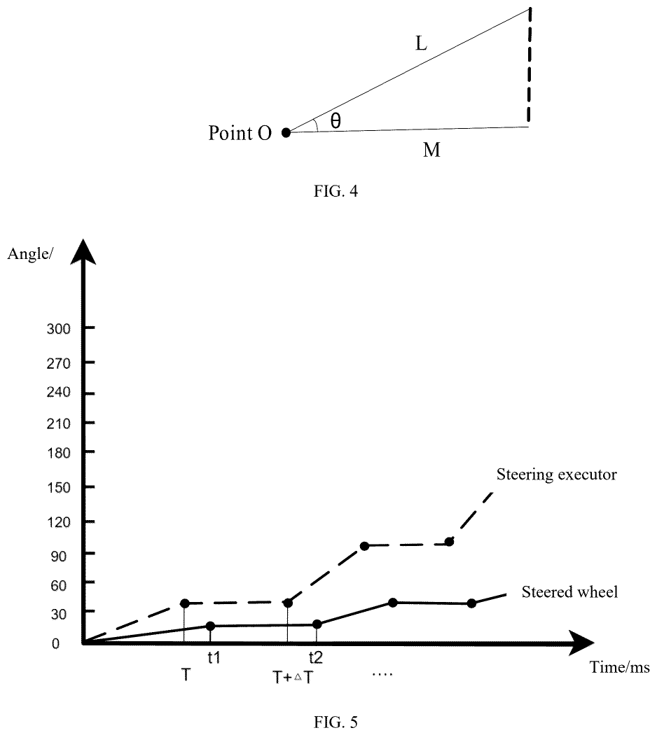

In order to facilitate intuitive understanding for the testing results, in the example disclosed by the present application, as shown in FIG. 5, a steering comparison diagram between the steering executor 1 and the steered wheel 6 is drawn in a following manner.

A curve (represented by a solid line) of the steering executor 1 and a curve (represented by a dashed line) of the steered wheel 6 are drawn, with sampling time as the horizontal axis and a rotation angle as the longitudinal axis,

As shown in FIG. 5, in the first steering process, the steering executor 1 (represented by a dashed line) rotates to an angle θ within time of 0 to T, and then keeps the angle for the time ΔT. The steered wheel 6 (represented by a solid line) rotates to an angle Φ within time of 0 to t1. At this moment, a steering delay of the steered wheel 6 relative to the steering executor 1 in the first steering process may be calculated as t1−T. Similarly, a corresponding steering delay may be calculated in each steering process later.

The steering delay unit is further used for screening out the maximum steering delay according to the steering delay of each steering of the steered wheel 6, calculating an average steering delay, and taking the maximum steering delay and the average steering delay as a steering function testing result.

In one example disclosed by the present application, the testing result unit further includes a parameter comparison unit.

The parameter comparison unit is in communication connection with a vehicle speed sensor on the vehicle 7, and used for obtaining the actual rotation angle of the steered wheel 6 and the actual steering angle of the steering executor 1 with regard to each set vehicle speed when the steering executor 1 receives the same steering instruction at a plurality of set vehicle speeds, and calculating an actual steering ratio at the set vehicle speed according to a following formula:

$$Actual steering ratio = \frac{Actual steering angle of steering executor}{Actual rotation angle of steered wheel}$$

For example, a plurality of target vehicle speeds (such as a low speed, a medium speed, and a high speed) are set, and the vehicle 7 is enabled to execute the same steering instruction at the different vehicle speeds. An actual steering ratio is calculated with regard to each target vehicle speed.

The actual steering ratio at each set vehicle speed is compared with a corresponding preset steering ratio parameter (the steering ratio parameter is set by a vehicle manufacturer, for example, the corresponding steering ratio parameter at the low speed is A, the corresponding steering ratio parameter at the medium speed is B, and the corresponding steering ratio parameter at the high speed is C), and a difference value between the actual steering ratio and the steering ratio parameter is calculated as a steering ratio error in the steering function testing result.

Through setting the different vehicle speeds, the actual steering ratios at the different vehicle speeds are obtained through calculation, and compared with the steering parameters set by the vehicle manufacturer, so that whether a steering ratio adjustment function is influenced by an electromagnetic environment or not may be determined.

In one example disclosed by the present application, the parameter comparison unit is further in communication connection with the steering executor 1, and used for, when the vehicle speed is fixed or the vehicle 7 stops running, obtaining a current rotation angle of the steering executor 1, that is, an angle that the steering executor 1 rotates compared with set 0 degree. A theoretical rotation angle of the steered wheel 6 is calculated according to an angle ratio parameter preset by the vehicle manufacturer (i.e., a ratio between the rotation angle of the steering wheel 5 and the rotation angle of the steered wheel 6). For example, if 1-degree rotation of the steering wheel 5 is expected to drive 0.5-degree rotation of the steered wheel 6, the theoretical rotation angle of the steered wheel 6=a current angle of the steering wheel 5×0.5.

A current actual rotation angle of the steered wheel 6 is obtained according to the radius of the checkerboard 2 and the distance parallel to the running ground and between the midpoint and the edge of the checkerboard 2 in a currently-shot image, and a difference value between the theoretical rotation angle and the actual rotation angle is calculated as a rotation angle error between the steered wheel 6 and the steering executor 1 in the steering function testing result.

When the vehicle speed is fixed or in a static state, the theoretical rotation angle of the steered wheel 6 may be obtained through carrying out mathematic calculation on the angle data of the steering executor 1 on the steering wheel 5 and the parameters provided by the vehicle manufacturer, and through comparing the theoretical rotation angle with the actual rotation angle of the steered wheel 6, the rotation angle error is obtained.

In one example disclosed by the present application, the testing result unit further includes an alignment unit.

The alignment unit is in communication connection with the parameter comparison unit, and used for obtaining rotation angle errors between the steered wheel 6 and the steering executor 1 when the steering executor 1 rotates to the left and right by the same angle from the set 0 degree.

The alignment unit receives rotation angle error data calculated by the parameter comparison unit. When the steering executor 1 respectively rotates to the left and right by the same angle, the parameter comparison unit will calculate rotation angle errors between the steering executor 1 and the steered wheel 6, and respectively obtain a left-rotating error and a right-rotating error.

The alignment unit compares the left-rotating error with the right-rotating error, and calculates a difference value between the left-rotating error and the right-rotating error, and the difference value is an alignment error which is used for reflecting whether a steering system in the left direction and the right direction keeps a consistent response characteristic or not.

The alignment unit compares the alignment error obtained through calculation with a preset alignment error threshold value of the system. If the alignment error value exceeds the threshold value, it is determined that alignment between left steering and right steering is abnormal, which indicates that the response characteristics of the left steering and the right steering are inconsistent.

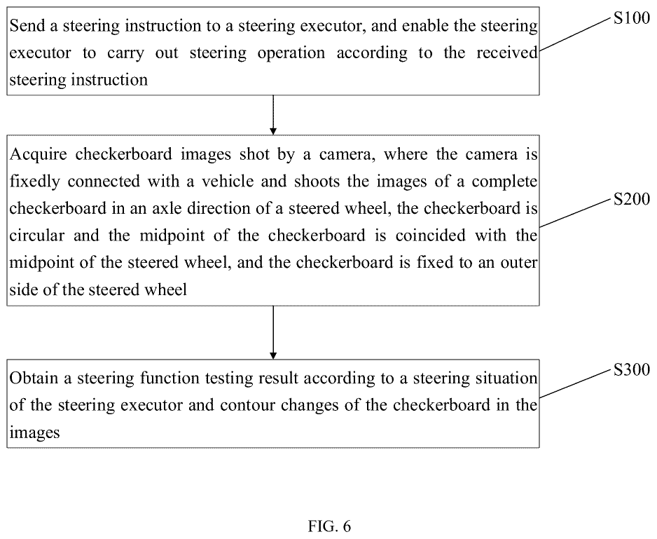

FIG. 6 is a schematic flow diagram of a steer-by-wire electromagnetic-compatibility testing method for an intelligent connected vehicle, which is provided by the example of the present application, and the method is applied to the steer-by-wire electromagnetic-compatibility testing system for the intelligent connected vehicle, which is provided by the above example. As shown in FIG. 6, the method includes the following steps:
step S100: sending a steering instruction to a steering executor, and enabling the steering executor to carry out steering operation according to the received steering instruction;
step S200: acquiring checkerboard images shot by a camera, where the camera is fixedly connected with the vehicle 7 and shoots the images of a complete checkerboard in an axle direction of a steered wheel 6, the checkerboard is circular and the midpoint of the checkerboard is coincided with the midpoint of the steered wheel 6, and the checkerboard is fixed to an outer side of the steered wheel 6; and
step S300: obtaining a steering function testing result according to a steering situation of the steering executor and contour changes of the checkerboard in the images.

The above example may be referred to for the contents in the testing method, which will not be further elaborated herein.

In one example disclosed by the present application, the step S300 may be completed in a following manner.

Firstly, a steering instruction is generated according to steering data input by a user, and sent to the steering executor. The steering data includes a steering speed, a steering angle, step time, and dwell time.

Secondly, after a shooting instruction is received, the camera is controlled to continuously shoot the images of the checkerboard, and each image and shooting time are stored.

Thirdly, the first starting time

$${t}_{i}^{begin}$$

and the first stopping time

$${t}_{i}^{end}$$

of the ith steering of the steered wheel 6 are obtained, as well as a distance L parallel to a running ground and between the midpoint and an edge of the checkerboard in the image corresponding to

$${t}_{i}^{begin} ,$$

and a distance M parallel to the running ground and between the midpoint and the edge of the checkerboard in the image corresponding to

$${t}_{i}^{end}$$

are obtained, and an actual rotation angle θᵢ of the steered wheel 6 during the ith steering is calculated according to a following formula.

$${θ}_{i} = {cos}^{- 1} \frac{M}{L}$$

wherein 1≤i≤n, and n is a total number of steering times of the steered wheel 6 during testing; and
   Lastly, the second starting time

$${T}_{i}^{begin} ,$$

the second stopping time

$${T}_{i}^{end} ,$$

and an actual steering angle Φᵢ when the steering executor executes steering action for the ith time are acquired, and a steering function testing result is obtained according to the starting time

$${T}_{i}^{begin} ,$$

the stopping time

$${T}_{i}^{end} ,$$

and the actual rotation angle Φᵢ of the ith steering of the steered wheel 6, where the steering function testing result at least includes a steering angle error and a steering delay.

The examples of the present application have been described above, and the above description is exemplary, not exhaustive, and not limited to the disclosed examples. Without departing from the scope and spirit of the described examples, many modifications and variations will be obvious to those of ordinary skill in the art. Selection for the terms used herein aims to best explain the principles of the examples, practical applications, or technical improvements for technologies in the market, or to enable other ordinary skilled in the art to understand the examples disclosed herein.

What is claimed is:

1. A steer-by-wire electromagnetic-compatibility testing system for an intelligent connected vehicle, applied to test a steer-by-wire function of the vehicle in an electromagnetic environment, comprising:
a steering executor fixed to a steering wheel, configured to carry out steering operation according to a received steering instruction;
a circular checkerboard fixed to an outer side of a steered wheel, wherein a midpoint of the checkerboard is coincided with a midpoint of the steered wheel;
a camera fixedly connected with the vehicle, configured to shoot images of a complete checkerboard in an axle direction of the steered wheel; and
a processor in communication connection with the steering executor and the camera, configured to send a steering instruction to the steering executor, acquire checkerboard images shot by the camera, and obtain a steering function testing result according to a steering situation of the steering executor and contour changes of the checkerboard in the images;
wherein the processor comprises a steering instruction unit, the steering instruction unit is in communication connection with the steering executor, and configured to generate the steering instruction according to steering data input by a user, and send the steering instruction to the steering executor, the steering data comprises a steering speed ω, a steering angle θ, a step time ΔT1, and a dwell time ΔT2, the vehicle is enabled to rotate by the angle θ at the steering speed o and then run for the time ΔT1, and then stop running for the time ΔT2, and the process is repeated for multiple times;
the processor further comprises the following units:
an image unit in communication connection with the camera, configured to, after receiving a shooting instruction, control the camera to continuously shoot the images of the checkerboard, and store each image and shooting time;
an analysis unit in communication connection with the image unit, configured to obtain a first starting time
$${t}_{i}^{begin}$$
and a first stopping time
$${t}_{i}^{end}$$
of the ith steering of the steered wheel, as well as to obtain a distance L parallel to a running ground and between the midpoint and an edge of the checkerboard in the image corresponding to
$${t}_{i}^{begin} ,$$
and a distance M parallel to the running ground and between the midpoint and the edge of the checkerboard in the image corresponding to
$${t}_{i}^{end} ,$$
and calculate an actual rotation angle θᵢ of the steered wheel during the ith steering according to a following formula:
$${θ}_{i} = {cos}^{- 1} \frac{M}{L}$$
wherein 1≤i≤n, and n is a total number of steering times of the steered wheel during testing; and
a testing result unit in communication connection with the analysis unit and the steering executor, configured to acquire a second starting time
$${T}_{i}^{begin} ,$$
a second stopping time
$${T}_{i}^{end} ,$$
and an actual steering angle Φᵢ when the steering executor executes steering action for the ith time, and obtain a steering function testing result according to the first starting time
$${t}_{i}^{begin} ,$$
the first stopping time
$${t}_{i}^{end} ,$$
and the actual rotation angle θᵢ of the ith steering of the steered wheel, wherein the steering function testing result at least comprises a steering angle error and a steering delay.

2. The testing system according to claim 1, wherein a radius of the checkerboard is less than a radius of the steered wheel.

3. The testing system according to claim 1, wherein the camera is a high-speed camera, and a center point of an optical axis is located on an extension line of the axle direction.

4. The testing system according to claim 1, wherein the testing result unit comprises the following sub-units:
a steering angle error unit, configured to calculate a steering angle error of the steered wheel relative to the steering executor after the ith steering according to the actual rotation angle of the steered wheel after the ith steering and the actual steering angle of the steering executor after executing steering action for the ith time; and
a steering delay unit, configured to calculate a steering delay of the steered wheel relative to the steering executor after the ith steering according to the first starting time and the first stopping time of the ith steering of the steered wheel, as well as the second starting time and the second stopping time when the steering executor executes steering action for the ith time;
wherein the steering delay unit is further configured to obtain a maximum steering delay and an average steering delay according to the steering delay of each steering of the steered wheel.

5. The testing system according to claim 1, wherein the testing result unit further comprises:
a parameter comparison unit in communication connection with a vehicle speed sensor on the vehicle, configured to obtain the actual rotation angle of the steered wheel and the actual steering angle of the steering executor with regard to each set vehicle speed when the steering executor receives a same steering instruction at a plurality of set vehicle speeds, and calculate an actual steering ratio at the set vehicle speed according to a following formula:
$$actual steering ratio = \frac{Actual steering angle of steering executor}{Actual rotation angle of steered wheel} ;$$
wherein, the actual steering ratio at each set vehicle speed is compared with a corresponding preset steering ratio parameter, and a difference value between the actual steering ratio and the steering ratio parameter is calculated, the difference value between the actual steering ratio and the steering ratio parameter is as a steering ratio error in the steering function testing result.

6. The testing system according to claim 5, wherein the parameter comparison unit is further in communication connection with the steering executor, and configured to obtain a current rotation angle of the steering executor when the steering wheel is in a static state, and calculate a theoretical rotation angle of the steered wheel according to a preset angle ratio parameter; and
the parameter comparison unit is further configured to obtain a current actual rotation angle of the steered wheel according to the radius of the checkerboard and the distance parallel to the running ground and between the midpoint and the edge of the checkerboard in a currently-shot image, and calculate a difference value between the theoretical rotation angle and the actual rotation angle as a rotation angle error between the steered wheel and the steering executor in the steering function testing result.

7. The testing system according to claim 6, wherein the testing result unit further comprises:
an alignment unit in communication connection with the parameter comparison unit, configured to obtain rotation angle errors between the steered wheel and the steering executor when the steering executor rotates to the left and right by the same angle; and
the alignment unit is further configured to calculate a difference value between the two errors as an alignment error in the steering function testing result, and determine that left-right alignment is abnormal when the alignment error is greater than a preset threshold value.

8. A steer-by-wire electromagnetic-compatibility testing method for an intelligent connected vehicle, applied to the steer-by-wire electromagnetic-compatibility testing system for the intelligent connected vehicle according to claim 1, comprising:
sending the steering instruction to the steering executor, and enabling the steering executor to carry out steering operation according to the received steering instruction;
acquiring checkerboard images shot by the camera, wherein the camera is fixedly connected with the vehicle and shoots the images of the complete checkerboard in the axle direction of the steered wheel; the checkerboard is circular and the midpoint of the checkerboard is coincided with the midpoint of the steered wheel, and the checkerboard is fixed to an outer side of the steered wheel;
obtaining the steering function testing result according to the steering situation of the steering executor and contour changes of the checkerboard in the images, comprising:
generating the steering instruction according to the steering data input by the user, and sending the steering instruction to the steering executor, wherein the steering data comprises the steering speed ω, the steering angle θ, the step time ΔT1, and the dwell time ΔT2, the vehicle is enabled to rotate by the angle θ at the steering speed o and then run for the time ΔT1, and then stop running for the time ΔT2, and the process is repeated for multiple times;
after receiving a shooting instruction, controlling the camera to continuously shoot the images of the checkerboard, and storing each image and shooting time;
obtaining the first starting time
$${t}_{i}^{begin}$$
and the first stopping time
$${t}_{i}^{end}$$
of the ith steering of the steered wheel, as well as obtaining the distance L parallel to the running ground and between the midpoint and the edge of the checkerboard in the image corresponding to
$${t}_{i}^{begin} ,$$
and the distance M parallel to the running ground and between the midpoint and the edge of the checkerboard in the image corresponding to
$${t}_{i}^{end} ,$$
and calculating the actual rotation angle θᵢ of the steered wheel during the ith steering according to the following formula:
$${θ}_{i} = {cos}^{- 1} \frac{M}{L}$$
wherein 1≤i≤n, and n is a total number of steering times of the steered wheel during testing; and
acquiring the second starting time
$${T}_{i}^{begin} ,$$
the second stopping time
$${T}_{i}^{end} ,$$
and the actual steering angle Φᵢ when the steering executor executes steering action for the ith time, and obtaining the steering function testing result according to the starting time
$${t}_{i}^{begin} ,$$
the stopping time
$${t}_{i}^{end} ,$$
and the actual rotation angle θᵢ of the ith steering of the steered wheel, wherein the steering function testing result at least comprises the steering angle error and the steering delay.
